(19) United States
(12) Patent Application Publication
(10) Pub. No.: US 2022/0190213 A1
(43) Pub. Date: Jun. 16, 2022

(54) MATERIAL STACK FOR LEDS WITH A DOME

(71) Applicant: Lumileds LLC, San Jose, CA (US)

(72) Inventors: Grigoriy Basin, San Francisco, CA (US); Michael Holub, Santa Clara, CA (US); Ted Mihopoulos, Mountain View, CA (US); Rafiza Ramli, Penang (MY); Tze Yang Hin, Cupertino, CA (US)

(21) Appl. No.: 17/122,978

(22) Filed: Dec. 15, 2020

(51) Int. Cl. H01L 33/54; H01L 33/50; H01L 33/62; H01L 33/58; H01L 33/56

(52) U.S. Cl. CPC H01L 33/54; H01L 33/502; H01L 33/56; H01L 33/58; H01L 33/62

(57) ABSTRACT

Various embodiments include methods for forming domed light-emitting diode (LED)-modules and devices constructed by those methods. In one example, the domed LED-module includes a package substrate, an LED die formed on the package substrate, one or more silicone pads formed on the package substrate and at least partially surrounding the LED die, and a high refractive-index material formed over the one or more silicone pads. Other devices and methods are described.

### TECHNICAL FIELD

The subject matter disclosed herein relates to a light-emitting diode (LED), a means to mount the LED to a substrate, and a stack of materials to form an encapsulating dome over the LED, thereby forming a domed LED-module. More specifically, the disclosed subject matter relates to a technique to form a material-stack proximate to an LED, along with a dome to both protect the LED and direct a radiation pattern of the LED. The disclosed subject matter further reduces or eliminates cracking and/or delamination problems frequently associated with using the domed LED-module.

### BACKGROUND

In a light-emitting diode (LED) device, an LED element is frequently encapsulated so as to be protected from, for example, physical impact as well as direct a radiation pattern of the LED. In general, forming a resin over the LED element may serve as a form of encapsulating. For example, an epoxy resin, a silicone resin, or similar materials known in the art may be used. However, there is typically a mismatch between the thermo-mechanical properties of such materials and the substrate onto which they are disposed or otherwise formed, which can lead to cracking and delamination related failures.

The information described in this section is provided to offer the skilled artisan a context for the following disclosed subject matter and should not be considered as admitted prior art.

### BRIEF DESCRIPTION OF THE FIGURES

FIGS. 1A through 1D show various exemplary processing steps for forming a domed LED-module, the domed LED-module includes an LED element formed on a substrate with a high refractive-index dome formed thereover;

FIG. 2 shows a plan view of an example of an LED die-mounting pad that may be used with elements of the various processing steps shown in FIGS. 1A through 1D;

FIGS. 3A through 3C show embodiments of a completed version of a domed LED-module formed in accordance with various exemplary embodiments of the disclosed subject matter;

FIG. 4A shows plan views of results from accelerated testing of domed LED-modules of the prior art, showing cracking and delamination; and

FIG. 4B shows plan views of exemplary results from accelerated testing of domed LED-modules formed in accordance with various exemplary embodiments of the disclosed subject matter and showing no cracking or delamination.

### DETAILED DESCRIPTION

The disclosed subject matter will now be described in detail with reference to a few general and specific embodiments as illustrated in various ones of the accompanying drawings. In the following description, numerous specific details are set forth in order to provide a thorough understanding of the disclosed subject matter. It will be apparent, however, to one skilled in the art, that the disclosed subject matter may be practiced without some or all of these specific details. In other instances, well-known process steps or structures have not been described in detail so as not to obscure the disclosed subject matter.

Examples and related exemplary materials for forming domed LED-modules will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer generally to like elements throughout.

It will be understood that, although the terms first, second, third, etc. may be used herein to describe various elements. However, these elements should not be limited by these terms. These terms may be used to distinguish one element from another. For example, a first element may be termed a second element and a second element may be termed a first element without departing from the scope of the disclosed subject matter. As used herein, the term “and/or” may include any and all combinations of one or more of the associated listed items.

It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,” “lower,” “horizontal,” or “vertical” may be used herein to describe a relationship of one element, zone, or region relative to another element, zone, or region as illustrated in the figures. It will be understood that these terms are intended to encompass different orientations of the device in addition to an orientation depicted in the figures. Further, whether the LEDs, LED arrays, arrangements of layers within a domed LED, as well as related electrical components and/or electronic components are housed on one, two, or more electronics boards may also depend on design constraints and/or a specific application.

Semiconductor-based light-emitting devices or optical power-emitting-devices, such as devices that emit infrared (IR), visible (VIS), or ultraviolet (UV) optical power, are among the most efficient light sources currently available. These devices may include light emitting diodes, resonant-cavity light emitting diodes, vertical-cavity laser diodes, edge-emitting lasers, or the like (simply referred to herein as LEDs). Due to their compact size and low power requirements, LEDs may be attractive candidates for many different applications. For example, the LEDs may be used as light sources (e.g., flashlights and camera flashes) for hand-held battery-powered devices, such as cameras and cellular phones. LEDs may also be used, for example, for automotive lighting, heads-up display (HUD) lighting, horticultural lighting, street lighting, a torch for video, general illumination (e.g., home, shop, office and studio lighting, theater/stage lighting, and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro LED arrays, etc.) may be used for applications where enhanced brightness is desired or required.

As noted briefly above, LEDs are often encapsulated with one or more transparent lens domes to improve light extraction and achieve a desired radiation-distribution pattern. To prepare an economical package that is also substantially impact resistant, the dome is frequently formed from some type of plastic material, such as a polymer. However, a shape of the dome, and the material used to form the dome, can have detrimental effects on an overall reliability of the LED package, particularly when the dome-height to package-width aspect ratio becomes large. Such dome shapes are often required for applications demanding a narrow beam-width such as, for example, to form a directional light source.

In order to achieve a desired level of light extraction from an encapsulated LED (including up to a maximum level of light extraction), LED packages often use polymers with a high refractive-index, such as phenyl silicones. Dimethyl silicones can be used as an alternative, but dimethyl silicones have a lower refractive-index than phenyl silicones. Consequently, domes made with dimethyl silicones demonstrate a lower light output than domes made with phenyl silicones.

However, phenyl silicones with a high refractive-index generally cannot perform well in low temperature applications or in thermal-cycling reliability tests where the package is repeatedly transferred between temperatures from, for example, −40° C. to 125° C. or from −55° C. to 150° C. Industry-standard tests typically involve temperature ranges of −40° C. to 125° C. for purposes of product qualification and temperature ranges of −55° C. to 150° C. for purposes of overstress testing. At the interfacial surface between the phenyl silicone and a package substrate, significant stresses build up as these materials expand and contract at substantially different rates. The stresses eventually cannot be supported and are relieved through distortion, cracking, and/or delamination. Usually, the domes with high aspect-ratios (as defined above) delaminate from the substrates onto which they are moulded. The delamination crack or cracks continue to propagate with repeated thermal cycling and/or prolonged exposure to low temperature environments. In the worst case, the delamination can propagate to the LED chip and/or wire bonds resulting in a loss of function of the LED itself, resulting in no light being output from the package.

This delamination and cracking problem can be overcome by designing the LED in such a way so as to reduce, minimize, or absorb the interfacial stress and reduce the probability of cracking-related or delamination-related failures. Dimethyl silicones—owing to their low glass transition temperature, T_{g}, low modulus, and high elongation before breakage properties—can better withstand imposed reliability tests. However, the dimethyl silicones cannot match the light output achieved using silicones with a high refractive-index material of, for example, 1.53 and above.

As mentioned above, the domes of the packages with high-aspect ratios, such as bullet-shaped domes, which are used for some optical features of the LED packages, have some limitations in reliability tests. The phenyl silicones with a high refractive-index exhibit high glass-transition temperatures (e.g., T_{g} greater than about 0° C.), which means phenyl silicones generally cannot perform well in temperature reliability tests which need to transfer the condition of the packages from about −40° C. to about 125° C. Usually, the domes with certain aspect ratios of the dome delaminate from the substrates onto which the domes are moulded. The dimethyl silicones has a T_{g} of less than approximately −100° C. Due to the low value of T_{g}, dimethyl silicones can generally withstand thermal-reliability tests well. However, as noted above, the dimethyl silicones cannot match the light output that can be achieved with the silicones (e.g., phenyl silicones) having high refractive-indices of about 1.5 and above. Therefore, to achieve a high level of light output from a domed LED-module, coupled with a high reliability level of the domes, the domed LED-module of the disclosed subject matter is formed in several operations as outlined ins more detail below.

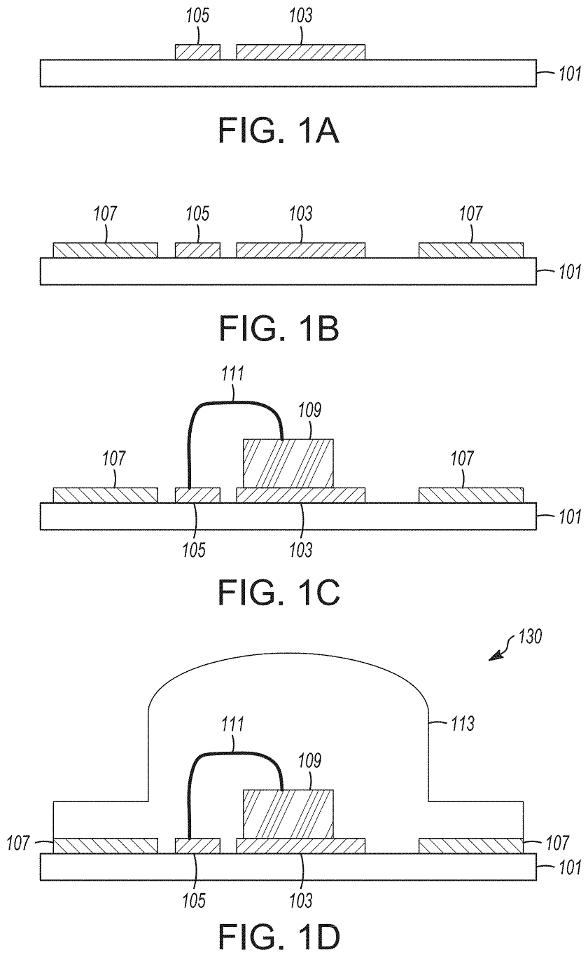

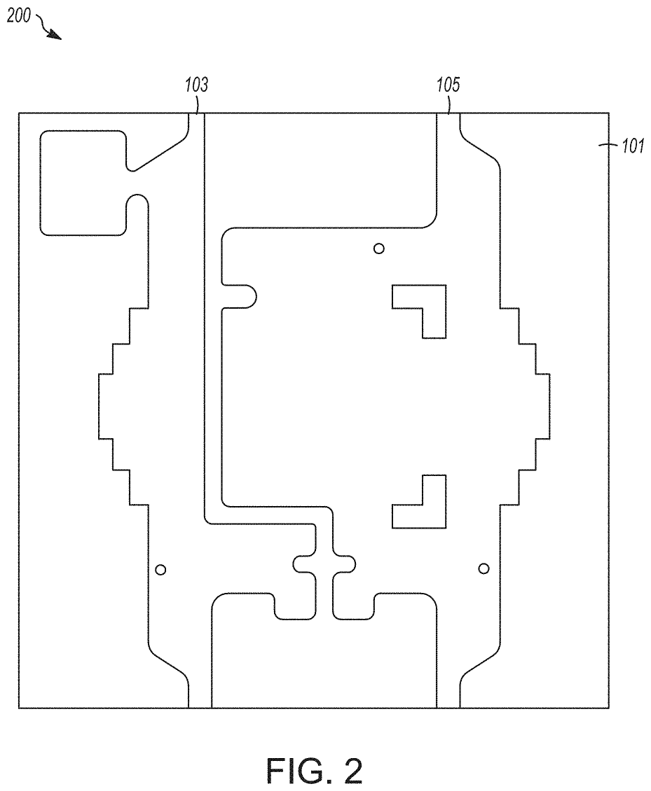

With reference now to FIGS. 1A through 1D, various exemplary processing steps for forming a domed LED-module are shown. Referring specifically to the cross-sectional elevation view of FIG. 1A, examples of an LED cathode-mount 103 and an LED anode-mount 105 are shown. The LED cathode-mount 103 and the LED anode-mount 105 are shown mounted on a package substrate 101. Generally interconnect wiring (not shown in FIG. 1A but understandable to a skilled artisan) extends from each of the LED cathode-mount 103 and the LED anode-mount 105 through the package substrate 101, thereby allowing an external electrical connection to an LED die that is mounted in a subsequent processing step. Upon reading and understanding the disclosed subject matter, a person of ordinary skill in the art will recognize that the LED cathode-mount 103 and the LED anode-mount 105 are shown merely as an example and may appear differently or be reversed in the order shown. That is, the LED cathode-mount may be element number 105 and the LED anode-mount may be element number 103. Each of the LED mounts is discussed in more detail with reference to FIG. 2, below.

The LED cathode-mount 103 and the LED anode-mount 105 may each be formed by various methods such as by techniques such as, for example, plating or screen printing a metallic area or pattern onto the package substrate 101, lithographically etching a thin metallic layer (not shown directly but understandable to a skilled artisan) formed on the package substrate 101, or by a number of other techniques known in the art. The package substrate 101 may comprise any of various types of substrates known in the relevant art, such as ceramic substrates, glass or quartz substrates, or various types of high-temperature plastic substrates.

FIG. 1B is shown to include one or more silicone pads 107 printed or otherwise formed proximate to the LED cathode-mount 103 and the LED anode-mount 105. For example, the one or more silicone pads 107 may be printed or formed on the package substrate 101 by selective depositions such as screen printing or by selective-dispense techniques. In various embodiments, the one or more silicone pads 107 may have a thickness of (measured relative from an upper surface of the package substrate 101 to an upper surface of the one or more silicone pads 107), for example, 5 μm (or less) to several hundred microns (or more). In various embodiments, the one or more silicone pads 107 may comprise multiple layers. For the one or more silicone pads 107 to be most effective, it is desired to maximize the area covered on the package substrate 101 but not encroach into the wire bond or LED die area. In certain exemplary embodiments, and depending at least partially on a particular application, it may be desirable for the one or more silicone pads 107 to be present at an entire perimeter of the dome where delamination cracks may initiate.

The one or more silicone pads 107 may also include or contain a white colorant in the form of high refractive-index particles dispersed within the one or more silicone pads 107 comprising particles such as titanium oxide, zinc oxide, aluminum oxide, magnesium oxide, or similar materials. The white colorant results in a high-reflectance surface-coating for the LED package, which further improves light output.

The one or more silicone pads 107 comprise a silicone-based organic polymer have a T_{g} of at least less than about −40° C. In one specific exemplary embodiment, the one or more silicone pads 107 may comprise, for example, a low refractive-index silicone with a low glass-transition temperature. T_{g}, of less than about −40° C. In other embodiments, the one or more silicone pads 107 may comprise, for example, a low refractive-index silicone with a low glass-transition temperature, T_{g}, of less than about −100° C. The temperature of less than about −55° C. provides a capability for a final version of the domed LED-module to comply with the lower temperature limit of a thermal-cycling reliability test where the package is repeatedly transferred between temperatures from about −55° C. to about 150° C. Depending upon a desired application, the one or more silicone pads 107 may possess a T_{g} below a minimum-expected temperature limit such that no significant thermo-mechanical changes occur within the one or more silicone pads 107 during thermal cycling. If the one or more silicone pads 107 go through a glass transition phase, then its modulus and CTE can change significantly. Consequently. an ability for the one or more silicone pads 107 to reduce, minimize, or absorb the interfacial stress can be impaired.

Since FIG. 1B shows a cross-sectional elevational view, the skilled artisan will recognize that the one or more silicone pads 107 may actually be a single silicone pad that surrounds the LED cathode-mount 103 and the LED anode-mount 105. Consequently, the one or more silicone pads 107 may be a single continuous silicone pad that encircles or is otherwise formed substantially continuously around the LED cathode-mount 103 and the LED anode-mount 105. In a specific exemplary embodiment, the one or more silicone pads 107 comprise a dimethyl silicone compound. In other exemplary embodiments, the one or more silicone pads comprise a silicone-based organic polymer having a T_{g} of at least less than about −40° C. In still other exemplary embodiments, the one or more silicone pads 107 comprise multiple silicone-based organic polymers, each having a T_{g} of at least less than about −40° C. In various embodiments, the one or more silicone pads 107 may have a refractive-index of less than about 1.5, although the refractive index is relatively unimportant for this component of a final version of the domed LED-module.

With reference now to FIG. 1C, an LED die 109 is attached to the LED anode-mount 105 and is further coupled to the LED cathode-mount 103 by an electrical-coupling element 111, such as a wire bond.

FIG. 1D is shown to include a substantially completed version of the domed LED-module 130 in which a high refractive-index dome 113 has been formed over the LED die 109, the LED cathode-mount 103 and the LED anode-mount 105, and the one or more silicone pads 107. The high refractive-index dome 113 may be formed by, for example, compression-moulding techniques known in the art (e.g., where the mould material is first heated, then compressed, and then cooled). In various embodiments, the high refractive-index dome 113 may be formed from a variety of materials known in the relevant art including various silicones, plastics, or glass materials. In a specific exemplary embodiment, the high refractive-index dome 113 comprises one or more types of phenyl silicones.

Note that, in various embodiments, it is permissible for the high refractive-index dome 113 to touch the package substrate 101 within the confines of the one or more silicone pads 107 since delamination cracks initiate at the perimeter of the dome and propagate inwards. As noted above, delamination is affected by interfacial stress and adhesion between the two materials—the package substrate 101 and the one or more silicone pads 107. Under schemes of the prior art, the edge of the substrate package and the edge of the dome perimeter is a region of high interfacial-stress (i.e., tensile stress normal to the substrate surface that would tend to cause the silicone to separate from the substrate). By reducing, minimizing, or absorbing the forces of stress in this region as noted by the disclosed subject matter, then a possibility of the crack initiating to the interior of the package is reduced greatly. Consequently, one of the functions of the one or more silicone pads 107 is to stop delamination cracks from initiating at the region of highest risk, at the outer perimeter of the dome. Therefore, in certain applications, the probability of delamination cracks forming can be reduced or minimized by not having the dome contact the substrate outside of a perimeter of the one or more silicone pads 107.

The high refractive-index dome 113 may be formed in accordance with a desired radiation-distribution pattern. For example, the high refractive-index dome 113 may be formed in a shape to focus radiation from the LED in a desired direction with a desired beam spread. Techniques for forming the high refractive-index dome 113 to have a desired radiation-distribution pattern or to focus radiation from the LED in a desired direction with a desired beam spread are known to a person of ordinary skill in the art. In various embodiments, the high refractive-index dome is formed from a material having a refractive index greater than about 1.5.

FIG. 2 shows a plan view of an example of an LED die-mounting pad 200 that may be used with the various processing steps shown in FIGS. 1A through 1D. As noted above, the LED die-mounting pad 200 includes the LED cathode-mount 103 and the LED anode-mount 105 described with reference to FIG. 1B et seq. above. Although the LED die 109 is described above as mounted on the LED die-mounting pad in a “vertical” orientation, being coupled to the LED cathode-mount 103 via an electrical-coupling element 111 (e.g., a wire bond), the skilled artisan, upon reading and understanding the disclosed subject matter, will recognize that the LED die 109 may also be mounted “horizontally” and other types of die-mounting techniques, such as surface-mount technologies (SMT), controlled collapse chip connection (C4), solder-bump mounting techniques, or other mounting techniques may also be used.

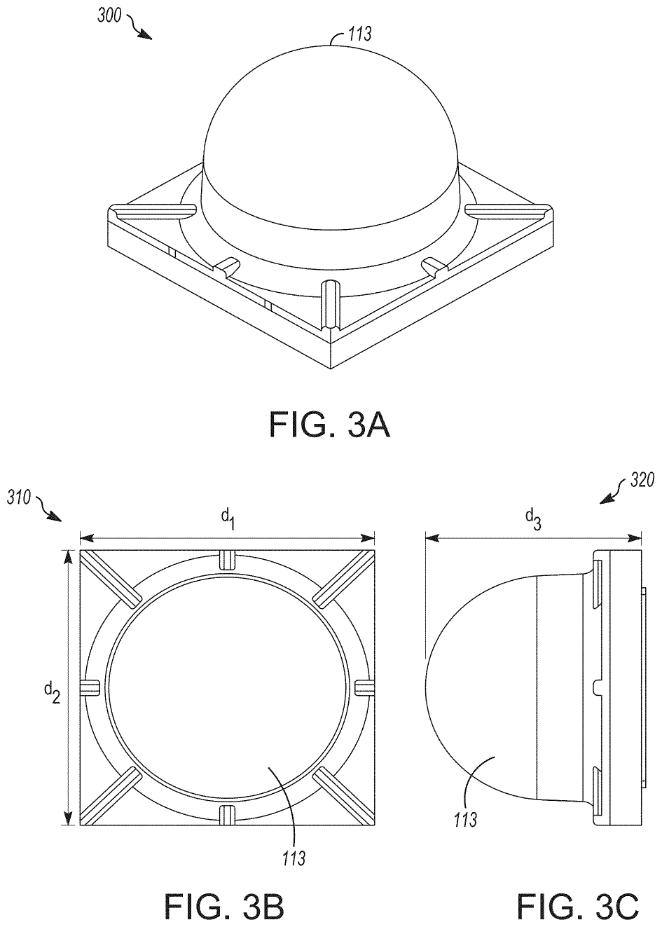

FIGS. 3A through 3C show embodiments of a completed version of a domed LED-module 130 (see FIG. 1D) formed in accordance with various exemplary embodiments of the disclosed subject matter. For example, FIG. 3A shows an embodiment of a three-dimensional drawing 300 of the domed LED-module 130.

FIG. 3B shows an example of a plan view 310 of the domed LED-module 130 indicating a first dimension d₁ and a second dimension d₂. In a specific exemplary embodiment, the first dimension d₁ and the second dimension d₂ are each the same, such as, for example, 3.7 mm each. In other embodiments, any range of similar or dissimilar dimensions of d₁ and d₂ may be chosen, depending at least in part on a desired application of, for example, industry-specific dimensions.

FIG. 3C shows an example of an elevational view 320 of the domed LED-module 130 indicating a third dimension d₃. In a specific exemplary embodiment, the third dimension d₃ may be in a range of, for example, 1.8 mm (or less) to 3.4 mm (or more). In other embodiments, any range of dimensions for d₃ may be chosen, depending at least in part on a desired application of industry-specific dimensions, a light distribution pattern, a desired level of radiant intensity of the light (e.g., in mW/sr), a desired beam angle, or other desired parameters.

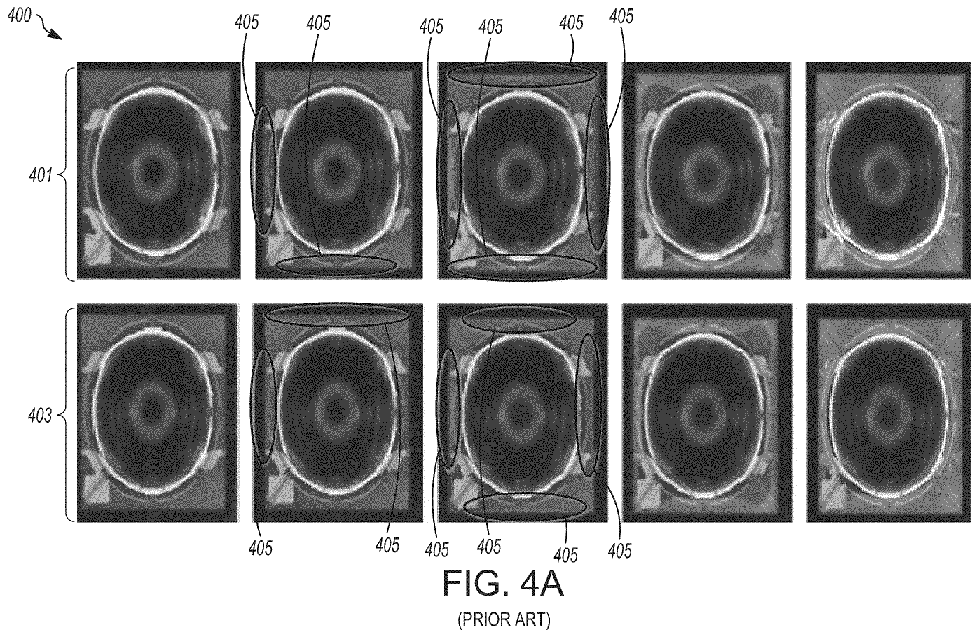

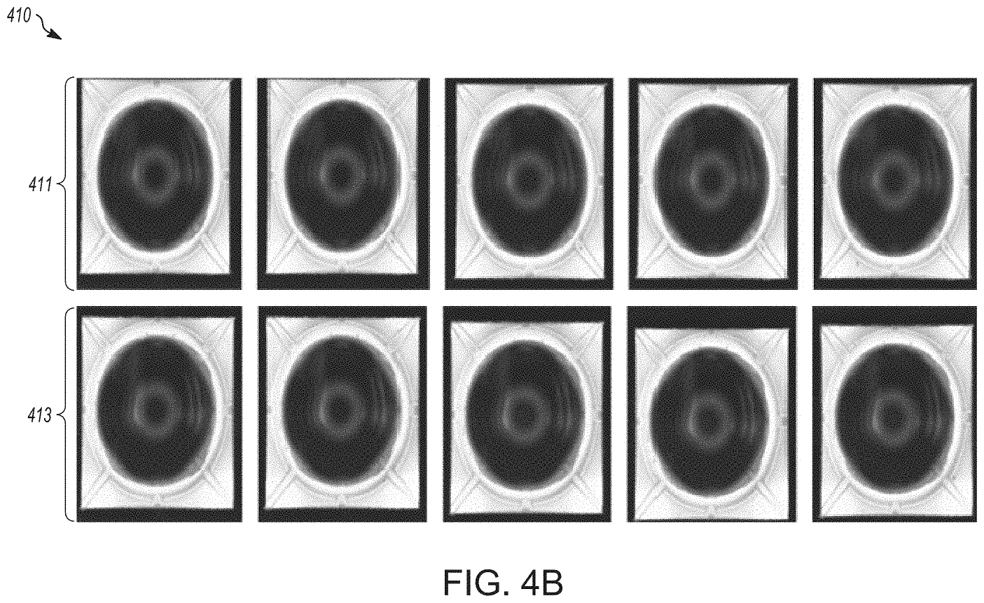

FIG. 4A shows plan views of results 400 from accelerated testing of domed LED-modules (two of the eight tested domed LED-modules are shown in this example) of the prior art, showing cracking and delamination after temperature stress-testing. The two domed LED-modules were both formed with a high refractive-index dome and were not formed in accordance with the disclosed subject matter provided herein. In this example, each of the eight domed LED-modules was subjected to a variety of thermal cycles in a powered thermo-mechanical cycling (PTMCL) stress test. The PTMCL test was conducted to subject the domed LED-modules to a range of temperatures, from −40° C. to 125° C., for a predetermined amount of time with a predetermined transfer time (e.g., 20 minutes) between temperatures.

In each of the two samples, 401 and 403, the first two views of the domed LED-modules (on the left as viewed on the drawing page when aligned horizontally) are shown prior to any thermal cycling (t=0 cycles). The next two views of the two domed LED-modules are shown after being subjected to 50 thermal cycles (t=50 cycles); the middle two views of the two domed LED-modules are shown after being subjected to 150 thermal cycles (t=150 cycles); the next two views of the two domed LED-modules are shown after being subjected to 500 thermal cycles (t=500 cycles); and the last two views of the two domed LED-modules are shown after being subjected to 1000 thermal cycles (t=1000 cycles). As shown in by the results 400 of FIG. 4A, each of the encircled areas 405 indicates areas of cracking and/or delamination of the domed LED-modules, starting by the time the first 50 thermal cycles have been completed.

In contrast to the plan views of results 400 of FIG. 4A, FIG. 4B shows plan views of exemplary results 410 from accelerated testing of domed LED-modules formed in accordance with various exemplary embodiments of the disclosed subject matter. The plan views of the exemplary results 410 of FIG. 4B show no cracking or delamination. The domed LED-modules were all formed with a high refractive-index dome formed over a low refractive-index coating in accordance with the disclosed subject matter provided herein. In this example, each of the eight domed LED-modules was subjected to a variety of thermal cycles in the TMCL stress test as defined above. That is, the PTMCL test was conducted to subject the domed LED-modules to a range of temperatures, from −40° C. to 125° C., for a predetermined amount of time with a predetermined transfer time (e.g., 20 minutes) between temperatures. In other thermal stress-testing (not shown), domed LED-modules were subjected to a thermal environment of −100° C. for a five-minute time period (a five-minute “thermal soak”), raised in temperature from −100° C. to 150° C. at a ramp rate of about 20° C. per minute, then kept in another thermal environment of 150° C. for another five-minute time period. In no case did the domed LED-modules show any indication of cracking or delamination.

For example, and with continuing reference to FIG. 4B, in each of the samples, 411 and 413, the first views of the two domed LED-modules (on the left as viewed on the drawing page when aligned horizontally) are shown prior to any thermal cycling (t=0 cycles). The next two views of the two domed LED-modules are shown after being subjected to 50 thermal cycles (t=50 cycles); the middle two views of the two domed LED-modules are shown after being subjected to 150 thermal cycles (t=150 cycles); the next two views of the two domed LED-modules are shown after being subjected to 500 thermal cycles (t=500 cycles); and the last views of the two domed LED-modules are shown after being subjected to 1000 thermal cycles (t=1000 cycles). As shown in by the exemplary results 410 of FIG. 4B, none of the domed LED-modules show any indication of cracking and/or delamination.

Various embodiments of the disclosed subject matter describes various transparent-polymer-lens domes to improve light extraction from an LED and achieve a desired radiation pattern. In various embodiments, described in detail herein, a silicone dome can be formed in few process steps. The first steps involve the application of a thin layer or layers of a low-refractive index material (e.g., methyl silicone or dimethyl silicone) over a surface of a package substrate surrounding an LED die. The thin layer or layers of low-refractive index materials reduce or eliminate delamination and/or cracking issues. In various embodiments, the thin layer or layers do not directly interfere with the optical path of the LED die emission. Subsequent steps involve moulding a dome of a high-refractive index, material, such as one or more layers of phenyl silicone, over the LED die.

In various embodiments described herein, the stack (e.g., comprising at least the one or more silicone pads 107 and the high refractive-index dome 113, which combined may comprise a silicone stack in various embodiments) has excellent reliability. The one or more silicone pads 107 (e.g., comprising methyl silicone) contacts the package substrate 101, acting as a stress absorber to reduce the package interfacial tensile-stress and dramatically reduce or eliminate the probability of delamination from the LED package.

The processing steps defined herein also offer a high level of light output since the direct optical path occurs through, for example, a high refractive-index phenyl silicone. Although the disclosed subject matter was based on using an infrared LED for the automotive market, the techniques and materials may generally be applied and can achieve the same outcome regardless of emission wavelength of the LED.

The description above includes illustrative examples, devices, and methods that embody the disclosed subject matter. In the description, for purposes of explanation, numerous specific details were set forth in order to provide an understanding of various embodiments of the disclosed subject matter. It will be evident, however, to those of ordinary skill in the art that various embodiments of the subject matter may be practiced without these specific details. Further, well-known structures, materials, and techniques have not been shown in detail, so as not to obscure the various illustrated embodiments.

As used herein, the term “or” may be construed in an inclusive or exclusive sense. Further, other embodiments will be understood by a person of ordinary skill in the art upon reading and understanding the disclosure provided. Further, upon reading and understanding the disclosure provided herein, the person of ordinary skill in the art will readily understand that various combinations of the techniques and examples provided herein may all be applied in various combinations. Further, the term “about,” as used herein, may be considered to be within a range of ±10% in particular embodiments. In other embodiments, the term “about” may be considered to be within a range of ±20%.

Although various embodiments are discussed separately, these separate embodiments are not intended to be considered as independent techniques, designs, or processing methods. As indicated above, each of the various portions may be inter-related and each may be used separately or in combination. Consequently, although various embodiments of methods, operations, and processes have been described, these methods, operations, and processes may be used either separately or in various combinations.

Consequently, many modifications and variations can be made, as will be apparent to a person of ordinary skill in the art upon reading and understanding the disclosure provided herein. Functionally equivalent methods and devices within the scope of the disclosure, in addition to those enumerated herein, will be apparent to the skilled artisan from the foregoing descriptions. Portions and features of some embodiments may be included in, or substituted for, those of others. Such modifications and variations are intended to fall within a scope of the appended claims. Therefore, the present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to allow the reader to quickly ascertain the nature of the technical disclosure. The abstract is submitted with the understanding that it will not be used to interpret or limit the claims. In addition, in the foregoing Detailed Description, it may be seen that various features may be grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

What is claimed is:

1. A domed light-emitting diode (LED)-module, the domed LED-module comprising:
a package substrate;
an LED die formed on the package substrate;
one or more silicone pads formed on the package substrate and at least partially surrounding the LED die; and
a high refractive-index material formed over the one or more silicone pads.

2. The domed LED-module of claim 1, wherein the one or more silicone pads comprise at least one layer of methyl silicone.

3. The domed LED-module of claim 1, wherein the one or more silicone pads may comprise a plurality of layers.

4. The domed LED-module of claim 1, further comprising a colorant comprised of high refractive-index particles dispersed within the one or more silicone pads.

5. The domed LED-module of claim 4, wherein high refractive-index particles are selected from one or more particle types including titanium oxide, zinc oxide, aluminum oxide, and magnesium oxide.

6. The domed LED-module of claim 1, further comprising a cathode mount and an anode mount formed on the package substrate, the cathode mount and the anode mount being configured to electrically couple to the LED die.

7. The domed LED-module of claim 1, wherein the high refractive-index material comprises at least one layer of phenyl silicone.

8. The domed LED-module of claim 1, wherein the high refractive-index material is formed in to achieve a desired radiation-distribution pattern.

9. The domed LED-module of claim 1, wherein the high refractive-index material is formed to achieve a desired formed to focus radiation from the LED die in a desired direction.

10. The domed LED-module of claim 1, wherein the high refractive-index material is formed to achieve a desired formed to focus radiation from the LED die with a desired beam spread.

11. The domed LED-module of claim 1, wherein the high refractive-index material has a refractive index of greater than about 1.5.

12. The domed LED-module of claim 1, wherein the one or more silicone pads have a glass-transition temperature of at least less than about −40° C.

13. A light-emitting diode (LED)-module, the LED-module comprising:
a package substrate;
an LED die formed on the package substrate;
one or more pads, comprising methyl silicone, formed on the package substrate and at least partially surrounding the LED die; and
a dome, comprising phenyl silicon, formed over the one or more silicone pads.

14. The LED-module of claim 13, further comprising a colorant comprised of high refractive-index particles dispersed within the one or more silicone pads.

15. The LED-module of claim 13, wherein the dome is formed in to achieve a desired radiation-distribution pattern.

16. The LED-module of claim 13, wherein the dome is formed to achieve a desired formed to focus radiation from the LED die in a desired direction.

17. The LED-module of claim 13, wherein the dome is formed to achieve a desired shape to focus radiation from the LED die with a desired beam spread.

18. A method of forming a domed light-emitting diode (LED)-module, the method comprising:
mounting an LED die on a package substrate;
forming one or more silicone pads formed on the package substrate, the one or more silicone pads at least partially surrounding the LED die; and
forming a high refractive-index material formed over the one or more silicone pads.

19. The method of claim 18, wherein the high refractive-index material is compression-moulded over the one or more silicone pads.

20. The method of claim 18, wherein the one or more silicone pads are formed to a thickness of at least about 5 μm.
